(19) United States
(12) Patent Application Publication
(10) Pub. No.: US 2012/0126198 A1
(43) Pub. Date: May 24, 2012

(54) LIGHT EMITTING DIODE FOR DROOP IMPROVEMENT

(75) Inventors: Shuji Nakamura, Santa Barbara, CA (US); Steven P. DenBaars, Goleta, CA (US); Shinichi Tanaka, Santa Barbara, CA (US); Junichi Sonoda, Kanagawa (JP); Hung Tse Chen, Goleta, CA (US); Chih-Chien Pan, Goleta, CA (US)

(73) Assignee: THE REGENTS OF THE UNIVERSITY OF CALIFORNIA, Oakland, CA (US)

(21) Appl. No.: 13/283,193

(22) Filed: Oct. 27, 2011

Related U.S. Application Data
(60) Provisional application No. 61/407,343, filed on Oct. 27, 2010.

(51) Int. Cl. H01L 33/04

(52) U.S. Cl. 257/9; 438/46; 257/13; 257/E33.008

(57) ABSTRACT

A light emitting diode (LED) device structure with a reduced Droop effect, and a method for fabricating the LED device structure. The LED is a III-nitride-based LED having an active layer or emitting layer comprised of a multi-quantum-well (MQW) structure, wherein there are eight or more quantum wells (QWs) in the MQW structure, and more preferably, at least nine QWs in the MQW structure. Moreover, the QWs in the MQW structure are grown at temperatures different from barrier layers in the MQW structure, wherein the barrier layers in the MQW structure are grown a temperatures at least 40° C. higher than the QWs in the MQW structure.

### CROSS REFERENCE TO RELATED APPLICATIONS

This application claims the benefit under 35 U.S.C. Section 119(e) of the following co-pending and commonly-assigned application:

U.S. Provisional Patent Application Ser. No. 61/407,343, filed on Oct. 27, 2010, by Shuji Nakamura, Steven P. DenBaars, Shinichi Tanaka, Junichi Sonoda, Hung Tse Chen, and Chih-Chien Pan, entitled “LIGHT EMITTING DIODE FOR DROOP IMPROVEMENT,” attorneys' docket number 30794.394-US-P1 (2011-169-1);

which application is incorporated by reference herein.

This application is related to the following co-pending and commonly-assigned applications:

U.S. Utility patent application Ser. No. ______, filed on Oct. 27, 2011, by Roy B. Chung, Changseok Han, Steven P. DenBaars, James S. Speck, and Shuji Nakamura, entitled “METHOD FOR REDUCTION OF EFFICIENCY DROOP USING AN (Al,In,Ga)N/Al(x)In(1-x)N SUPERLATTICE ELECTRON BLOCKING LAYER IN NITRIDE BASED LIGHT EMITTING DIODES,” attorneys' docket number 30794.399-US-U1 (2011-230-2), which application claims the benefit under 35 U.S.C. Section 119(e) of co-pending and commonly-assigned U.S. Provisional Patent Application Ser. No. 61/407,362, filed on Oct. 27, 2010, by Roy B. Chung, Changseok Han, Steven P. DenBaars, James S. Speck, and Shuji Nakamura, entitled “METHOD FOR REDUCTION OF EFFICIENCY DROOP USING AN (Al,In,Ga)N/Al(x)In(1-x)N SUPERLATTICE ELECTRON BLOCKING LAYER IN NITRIDE BASED LIGHT EMITTING DIODES,” attorneys' docket number 30794.399-US-P1 (2011-230-1);

U.S. Utility patent application Ser. No. ______, filed on Oct. 27, 2011, by Yuji Zhao, Junichi Sonoda, Chih-Chien Pan, Shinichi Tanaka, Steven P. DenBaars, and Shuji Nakamura, entitled “HIGH POWER, HIGH EFFICIENCY AND LOW EFFICIENCY DROOP III-NITRIDE LIGHT-EMITTING DIODES ON SEMIPOLAR {20-2-1} SUBSTRATES,” attorneys' docket number 30794.403-US-U1 (2011-258-2), which application claims the benefit under 35 U.S.C. Section 119(e) of co-pending and commonly-assigned U.S. Provisional Patent Application Ser. No. 61/407,357, filed on Oct. 27, 2010, by Yuji Zhao, Junichi Sonoda, Chih-Chien Pan, Shinichi Tanaka, Steven P. DenBaars, and Shuji Nakamura, entitled “HIGH POWER, HIGH EFFICIENCY AND LOW EFFICIENCY DROOP III-NITRIDE LIGHT-EMITTING DIODES ON SEMIPOLAR {20-2-1} SUBSTRATES,” attorneys' docket number 30794.403-US-P1 (2011-258-1);

U.S. Provisional Patent Application Ser. No. 61/495,829, filed on Jun. 10, 2011, by Shuji Nakamura, Steven P. DenBaars, Shinichi Tanaka, Daniel F. Feezell, Yuji Zhao, and Chih-Chien Pan, entitled “LOW DROOP LIGHT EMITTING DIODE STRUCTURE ON GALLIUM NITRIDE SEMIPOLAR {20-2-1} SUBSTRATES,” attorneys' docket number 30794.415-US-P1 (2011-832-1);

U.S. Provisional Patent Application Ser. No. 61/495,840, filed on Jun. 10, 2011, by Shuji Nakamura, Steven P. DenBaars, Daniel F. Feezell, Chih-Chien Pan, Yuji Zhao, and Shinichi Tanaka, entitled “HIGH EMISSION POWER AND LOW EFFICIENCY DROOP SEMIPOLAR {20-2-1} BLUE LIGHT EMITTING DIODES,” attorneys' docket number 30794.416-US-P1 (2011-833-1);

which applications are incorporated by reference herein.

### BACKGROUND OF THE INVENTION

1. Field of the Invention

The invention is related to the field of light emitting diodes (LEDs).

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Recently, the light emitting diode (LED) market has been spreading at rapid speed. Ten years ago, LED devices were only suitable for low brightness and low power applications, for example, as indicator lamps and the like.

At present, LEDs are also applicable for high brightness and high power devices (illumination, car headlamp, etc.) due to improvements in External Quantum Efficiency (EQE). However, LEDs still have a serious problem, known as “Droop,” wherein Droop is a decay of the EQE at high driving current.

There are different explanations proposed for Droop, such as current roll-over [1], carrier injection efficiency [2], polarization fields [3], Auger recombination [4], and junction heating [5].

Owing to this Droop, more LED chips are needed for high power devices, leading to higher prices. For example, car lamp assembly makers and illumination makers cannot completely shift to using LED devices because of their high cost. If the Droop problem is resolved, these makers will shift to LED devices completely, and the LED market will spread greatly.

Thus, there is a need in the art for LEDs where the Droop problem has been resolved. The present invention satisfies this need.

### SUMMARY OF THE INVENTION

To overcome the limitations in the prior art described above, and to overcome other limitations that will become apparent upon reading and understanding the present specification, the present invention discloses an LED device structure with a reduced Droop effect, and a method for fabricating the LED device structure. The LED is a III-nitride-based LED having an active layer or emitting layer comprised of a multi-quantum-well (MQW) structure, wherein there are eight or more quantum wells (QWs) in the MQW structure, and more preferably, at least nine QWs in the MQW structure. Moreover, the QWs in the MQW structure are grown at temperatures different from barrier layers in the MQW structure, wherein the barrier layers in the MQW structure are grown a temperatures at least 40° C. higher than the QWs in the MQW structure.

### BRIEF DESCRIPTION OF THE DRAWINGS

Referring now to the drawings in which like reference numbers represent corresponding parts throughout:

FIG. 1 is a schematic of a device structure according to one embodiment of the present invention.

FIG. 2 is a flow chart that describes a method for fabricating the device structure of FIG. 1 according to one embodiment of the present invention.

FIG. 3 is a graph that illustrates the emission power and EQE characteristics of a conventional 6 quantum well (QW) device at pulsed drive currents from 2 to 70 mA.

FIG. 4 is a graph that illustrates the emission power and EQE characteristics of an inventive 9 quantum well (QW) device at pulsed drive currents from 2 to 70 mA.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes an LED device structure with a reduced Droop effect, and a method for fabricating the LED device structure by growing device-quality, III-nitride-based, thin films via metalorganic chemical vapor deposition (MOCVD).

Device Structure

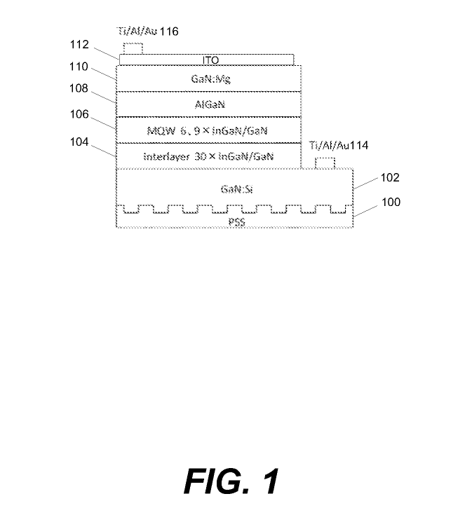

FIG. 1 is a schematic of a device structure according to one embodiment of the present invention. In this embodiment, the device structure comprises a Patterned Sapphire Substrate (PSS) LED that is a III-nitride LED.

The PSS-LED is grown on an n-GaN PSS template 100 by MOCVD, and includes a 1 μm n-type GaN:Si layer 102 followed by a mesa including an intermediate layer (interlayer) 104 comprised of a 30 period GaN/InGaN (4 nm/4 nm) superlattice, and an active layer or emitting layer 106 comprised of a multiple quantum well (MQW) structure.

In the PSS-LED of the present invention, the active layer 106 comprising the MQW structure has eight or more periods, wherein each period is comprised of 20 nm GaN barriers and a 4 nm InGaN quantum well (QW), with an ending barrier comprising a 16 nm thick GaN barrier. More preferably, the MQW structure has nine or more QWs. In contrast, the MQW structure of a conventional PSS-LED would have seven or less periods, i.e., seven or less QWs, and more likely, six or less QWs.

The MQW stack is followed by a 10 nm undoped Al_{0.15}Ga_{0.85}N electron blocking layer (EBL) 108, a 200 nm p-type GaN:Mg layer 110, and an indium tin oxide (ITO) transparent p-contact layer 112. Finally, an Ti/Al/Au based n-contact 114 is deposited on the n-type GaN:Si layer 102, and an Ti/Al/Au based p-pad 116 is deposited on the ITO transparent p-contact 112.

Fabrication Process

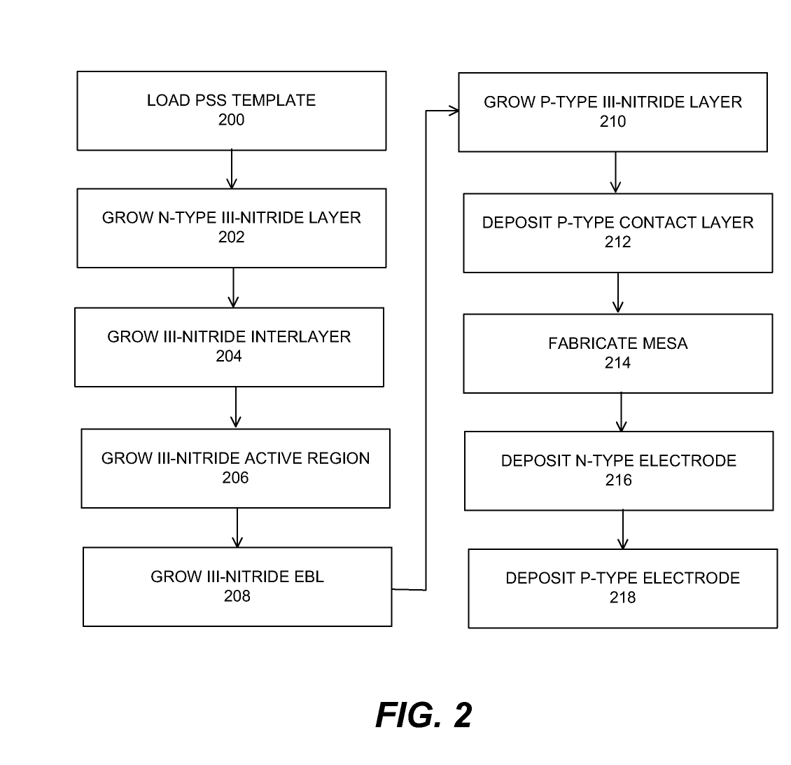

The PSS-LED shown in FIG. 1 was fabricated using the process steps shown in the flowchart of FIG. 2. Specifically, using these steps, one or more LEDs with 526×315 μm² mesa sizes were formed by conventional photolithography, followed by chlorine-based inductively coupled plasma (ICP) etching techniques to form the layers of the mesa.

Block 200 represents a PSS III-nitride template 100 being loaded into a metal organic chemical vapor deposition (MOCVD) reactor. In one embodiment, the PSS template 100 may be an n-GaN PSS template 100 fabricated on a c-plane sapphire substrate.

Block 202 represents the growth of an n-type III-nitride layer 102, e.g., an Si doped n-GaN layer, on the template 100.

Block 204 represents the growth of a III-nitride intermediate layer 104, e.g., a GaN/InGaN superlattice structure, on the n-GaN layer 102.

Block 206 represents the growth of a III-nitride active region 106, e.g., an InGaN/GaN MQW structure, on the GaN/InGaN superlattice structure 104.

Block 208 represents the growth of a III-nitride EBL 108, e.g., an undoped AlGaN EBL, on the active region 106.

Block 210 represents the growth of a p-type III-nitride layer 110, e.g., an Mg doped p-GaN layer, on the AlGaN EBL 108.

Block 212 represents the deposition of a transparent conducting oxide (TCO) layer 112, such as ITO, as a p-contact layer on the p-GaN layer 110.

Block 214 represents the fabrication of a mesa by patterning and etching.

Block 216 represents the deposition of a Ti/Al/Au n-type electrode 114 on the n-GaN layer 102 exposed by the mesa etch.

Block 218 represents the deposition of a Ti/Al/Au p-type electrode 116 on the p-contact layer 112.

Other steps not shown in FIG. 2 may also be performed, such as activation, annealing, dicing, mounting, bonding, encapsulating, packaging, etc.

Note that all MOCVD growth was performed at atmospheric pressure (AP).

The typical temperature range during MOCVD growth was approximately 1185° C. for the n-type GaN:Si layer 102, with a V/III ratio (e.g., the ratio of the NH₃ mole fraction to the trimethyl-gallium mole fraction) of 3000.

The active layer 106 was grown via MOCVD at approximately 850° C. and above with a V/III ratio of 12000. Moreover, the QWs in the MQW structure were grown at temperatures different from the barrier layers in the MQW structure. Specifically, the barrier layers in the MQW structure are grown a temperatures at least 40° C. higher than the QWs in the MQW structure. In one embodiment, the barrier layers in the MQW structure are grown at a temperatures of at least 920° C. and the QWs in the MQW structure are grown at a temperatures of at least 880° C.

The ITO transparent p-contact 112 was deposited by electron beam deposition. The Ti/Al/Au based n-contact 114 and p-pad 116 were then deposited on the n-GaN layer 102 and the ITO transparent p-contact 112, respectively.

The fabricated devices were packaged on a silver header encapsulated with a silicone dome.

Experimental Results

Following fabrication, the operation of the PSS-LED was examined. All measurements were carried out under pulsed operations at room temperature, and the optical emission power was measured in a calibrated integrating sphere.

The Droop ratio was calculated by Equation 1 below.

Droop ratio=(Max_EQE−EQE @60 mA)/Max_EQE*100(%) Eq. 1

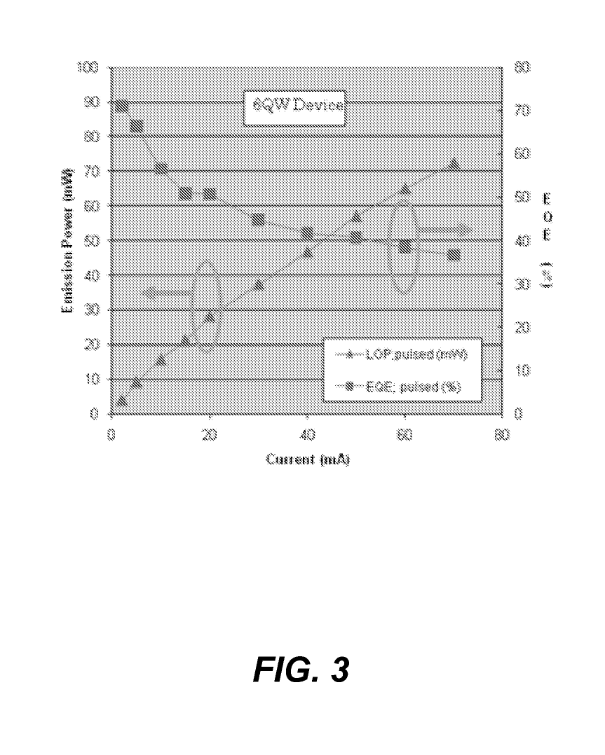

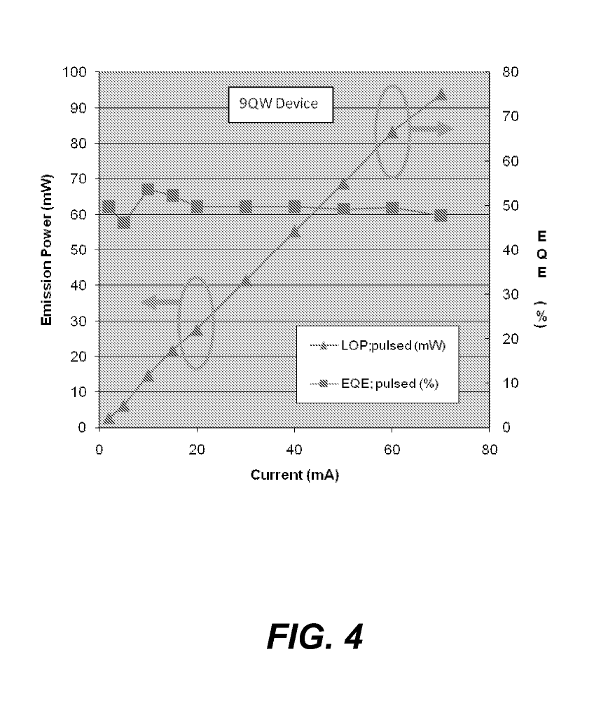

FIG. 3 is a graph that illustrates the emission power and EQE characteristics for a conventional device having 6 QWs in the MQW stack at pulsed drive currents from 2 to 70 mA, and FIG. 4 is a graph that illustrates the emission power and EQE characteristics for an inventive device according to the present invention having 9 QWs in the MQW stack at pulsed drive currents from 2 to 70 mA.

As shown in FIG. 3, at a current of 20 mA, the conventional 6 QW PSS-LED has a light output power (LOP) of 28.1 mW @ 447 nm and an EQE of 50.7%. However, the EQE of the conventional 6 QW device is greatly decreased by increasing drive currents. It is believed that this is because localized states having lower energy become saturated with increasing current, leading to blue shift and narrowing of the emission [3]. Moreover, more excitons will move to non-radiative sites such as various crystal faults, and as a result, the efficacy of emission will decrease.

In contrast to the conventional 6QW device, the inventive 9 QW PSS-LED has an LOP of 27.6 mW @ 447 nm and an EQE of 49.7% at a current of 20 mA, as shown in FIG. 4. The LOP of the inventive 9 QW PSS-LED remains linear with increasing drive current, even up to relatively high current density, and the EQE is almost constant, as can be seen in FIG. 4. This is a very promising.

The Droop characteristics of the conventional 6 QW and inventive 9 QW devices are shown in Table.1 below.

TABLE 1
The Droop characteristics of conventional 6 QW and
inventive 9 QW devices

EQE (%)

| Device | Max | 60 mA | Droop ratio (%) |
|---|---|---|---|
| 6 QW | 66.4 | 38.4 | 42.1 |
| 9 QW | 53.6 | 49.5 | 7.6 |

The Droop ratio of the conventional 6QW device is 42.1%. In contrast, the Droop ratio of the inventive 9 QW device is only 7.6%. This Droop ratio for the inventive 9 QW device is suitable for a commercially available product.

Possible Modifications and Variations

As noted above, the PSS III-nitride template may be an n-GaN PSS template. Alternatively, the PSS III-nitride template can be bulk III-nitride or a film of III-nitride. Moreover, the III-nitride may be a template layer or epilayer grown on a substrate, e.g., heteroepitaxially on a foreign substrate, such as sapphire or silicon carbide or other compound semiconductor substrates. Moreover, instead of an PSS III-nitride template, GaN, SiC, and other compound semiconductor substrates can be used in this invention.

Advantages and Improvements

The present invention describes an LED device structure and method for fabricating the LED device structure by growing device-quality, III-nitride-base, thin films via metalorganic chemical vapor deposition (MOCVD) on c-plane sapphire substrates. The present invention provides a pathway to III-nitride-based optoelectronic devices free from the Droop effect, since the temperature change growth of the QWs and the MQW structure having more than seven QWs will have minimal effect, if any, on (Al,In,Ga)N device layers grown on c-plane sapphire substrates.

In the present invention, an increased number of QWs results in less carrier density, and less carrier density will improve the Droop. Increasing the number of localized emission sites should be an effective method for improving Droop. Although, some explanations assert that the main reason of Droop is not dislocations [6] or Auger recombination [7], but instead carrier injection, transport, and leakage processes [8-10], this invention supports the belief that the main reasons for Droop are Auger recombination or current overflow.

And, it is believed that this improvement results from having more MQW layers in the active region. In the case of a conventional 6QW device, more excitons will move to non-radiative sites due to a lack of low energy localized sites. In the case of an inventive 9 QW device, because there are enough localized sites present, the excitons will not move to a non-radiative site. As a result, with an inventive device, the EQE remains constant with increasing drive current.

Nomenclature

The terms “III-nitride,” “Group-III nitride”, or “nitride,” as used herein refer to any alloy composition of the (Ga,Al,In,B)N semiconductors having the formula Ga_{w}AlₓIn_{y}B_{z}N where 0≦w≦1, 0≦x≦1, 0≦y≦1, 0≦z≦1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga,Al,In,B)N material species. Further, (Ga,Al,In,B)N materials within the scope of the invention may further include minor quantities of dopants and/or other impurity or inclusional materials.

### REFERENCES

The following references are incorporated by reference herein:
[1] B. Monemar and B. E. Sernelius, Appl. Phys. Lett. 91. 181103 (2007).
[2] I. V. Rozhansky and D. A. Zakheim, Semiconductor 40, 839 (2006).
[3] M. H. Kim, M. F. Schubert, Q. Dai, J. K. Kim, E. F. Schubert, J. Piprek, and Y. Park, Appl. Phys. Lett. 91, 183507 (2007).
[4] Y. C. Shen. G. O. Mueller, S. Watanabe, N. F. Gardner, A. Munkholm, and M. R. Krames, Appl. Phys. Lett. 91, 141101 (2007).
[5] A. A. Efremov, N. I. Bochkareva, R. I. Gorbunov, D. A. Larinovich, Yu. T. Rebane, D. V. Tarkhin, and Yu. G. Shreter, Semiconductors 40, 605 (2006).
[6] M. F. Schubert, S. Chajed, J. K. Kim, E. F. Schubert, D. D. Koleske, M. H. Crawford, S. R. Lee, A. J. Fischer, G. Thaler, and M. A. Nanas, Appl. Phys. Lett. 91, 231114 (2007).
[7] Y. C. Shen, G. O. Mueller, S. Watanabe, N. F. Gardner, A. Munkholm, and M. R. Krames, Appl. Phys. Lett. 91, 141101 (2007).
[8] A. R. Beattie and P. T. Landsberg, “Auger Effect in Semiconductors”, Proc. R. Soc. Lond. A. 249, 16 (1958).
[9] J. Xie, X. Ni, Q. Fan, R. Shimada, U. Ozgur, and H. Morkoc, Appl. Phys. Lett. In press.
[10] J. Hader, J. V. Moloney, B. Pasenow, S. W. Koch, M. Sabathil, N. Linder, and S. Lutgen, Appl. Phys. Lett.) 2, 261103 (2008).

### CONCLUSION

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating an optoelectronic device, comprising:
fabricating a III-nitride-based LED having an active layer comprised of a multi-quantum-well (MQW) structure, wherein there are eight or more quantum wells (QWs) in the MQW structure, and the QWs in the MQW structure are grown at temperatures different from barrier layers in the MQW structure.

2. The method of claim 1, wherein there are at least nine QWs in the MQW structure.

3. The method of claim 1, wherein the III-nitride-based LED has an improved Droop as compared to a III-nitride-based LED having an active layer with seven or less quantum wells (QWs).

4. The method of claim 1, wherein the barrier layers in the MQW structure are grown a temperatures at least 40° C. higher than the QWs in the MQW structure.

5. The method of claim 1, wherein the III-nitride-based LED has an external quantum efficiency (EQE) of approximately 50% or greater at a current greater than 20 mA and less than 70 mA.

6. The method of claim 1, wherein the III-nitride-based LED has an output power greater than 75 mW at a current of 60 mA or greater.

7. The method of claim 1, wherein the III-nitride-based LED has a Droop ratio of 40% or less at a current of 60 mA or greater.

8. An optoelectronic device fabricated using the method of claim 1.

9. An optoelectronic device, comprising:
a III-nitride-based LED having an active layer or emitting layer comprised of a multi-quantum-well (MQW) structure, wherein there are eight or more quantum wells (QWs) in the MQW structure, and the QWs in the MQW structure are grown at temperatures different from barrier layers in the MQW structure.

10. The device of claim 9, wherein there are at least nine QWs in the MQW structure.

11. The device of claim 9, wherein the III-nitride-based LED has an improved Droop as compared to a III-nitride-based LED having an active layer with seven or less quantum wells (QWs).

12. The device of claim 9, wherein the barrier layers in the MQW structure are grown a temperatures at least 40° C. higher than the QWs in the MQW structure.

13. The device of claim 9, wherein the III-nitride-based LED has an external quantum efficiency (EQE) of approximately 50% or greater at a current greater than 20 mA and less than 70 mA.

14. The device of claim 9, wherein the III-nitride-based LED has an output power greater than 75 mW at a current of 60 mA or greater.

15. The device of claim 9, wherein the III-nitride-based LED has a Droop ratio of 40% or less at a current of 60 mA or greater.
